(19) United States
(12) Patent Application Publication
(10) Pub. No.: US 2024/0035908 A1
(43) Pub. Date: Feb. 1, 2024

(54) METHOD FOR COMPRESSIVE MEASUREMENT OF THE STATISTICAL DISTRIBUTION OF A PHYSICAL QUANTITY

(71) Applicant: COMMISSARIAT À L'ÉNERGIE ATOMIQUE ET AUX ÉNERGIES ALTERNATIVES, Paris (FR)

(72) Inventors: William Guicquero, Grenoble (FR); Valentin Poisson, Grenoble (FR)

(21) Appl. No.: 18/256,588

(22) PCT Filed: Dec. 10, 2021
(86) PCT No.: PCT/FR2021/052284

§ 371 Date: Jun. 8, 2023

(30) Foreign Application Priority Data
Dec. 11, 2020 (FR) 2013100

(51) Int. Cl. G01L 5/16; G06F 17/18

(52) U.S. Cl. CPC G01L 5/16; G06F 17/18

(57) ABSTRACT

A method and a device for measuring the statistical distribution of a physical quantity by a sensor. At each observation of the physical quantity, the sensor provides, in the form of a binary vector, a quantised value of this quantity. Afterwards, this binary vector is projected onto a measurement space with a smaller dimension than the number of quantisation levels in order to provide a vector representative of the quantised value. The measurement vector of the histogram is updated on the fly by adding thereto the vector representative of the quantised value. Afterwards, this measurement vector may be used as an input variable of a neural network trained beforehand to predict a target variable dependent on the statistical distribution of the physical quantity.

### TECHNICAL FIELD

The present invention generally relates to the processing of information in a compressed form. In particular, it finds application in single photon detection devices or SPAD (Single Photon Avalanche Diode), in particular for imaging using such sensors.

### PRIOR ART

Single Photon Detection Devices (SPADs) are used in a wide range of fields, in particular in medical imaging, time-of-flight imaging, LIDAR imaging, positron emission tomography, etc.

The underlying principle of most of these imaging systems consists in measuring a time-of-flight (ToF) of an electromagnetic pulse emitted by a source synchronised with the acquisition system. In particular, a SPAD sensor allows measuring the round-trip time-of-flight of a pulse emitted by a light source reflected by an object to be imaged.

Although SPAD sensors have recently undergone considerable improvements in terms of consumption, temporal resolution or dynamics, the performances of these sensors face several constraints.

First of all, the time-of-flight information, which generally represents the useful information, is carried by the statistical distribution of the time-of-arrival of the photons on the sensor. In some cases, the useful signal is drowned in the noise which could represent up to 98% and even more of the total signal. Hence, it is necessary to perform a large number of successive acquisitions of the object to be imaged to obtain an acceptable signal-to-noise ratio.

Afterwards, the SPAD sensors should follow the evolution of imaging systems and therefore achieve high dynamics (or equivalently for time-of-flight imaging, high resolutions in distance) and high spatial resolutions. Consequently, each acquisition of one pixel of the imager assumes the ability to store and process a considerable number of bits and that being so over the smallest possible surface area.

Finally, the spatial resolution requirements of current imagers lead to a correlative increase in the number of pixels and therefore of photosites.

Ultimately, for a matrix in the range of one megapixel, with a frame rate in the range of 10 Hz, a time-of-flight encoded over 10 bits and one thousand acquisitions per pixel, 100 Gb/s are already reached at the output of the imager.

In order to reduce the amount of data generated per pixel, different histogram compression techniques have been proposed in the prior art.

A first technique, called “Partitioned Inter-frame Histogram” or PIfH, consists in dividing the dynamics of the time-of-flight distribution into intervals, the histograms relating to these intervals being obtained sequentially. This technique allows reducing the memory footprint per pixel but not reducing the amount of data generated by each pixel.

A second technique, called “Folded inter-frame Histogram” or FifH proceeds by zooming. A first analysis is performed with a coarse division of the time-of-flight dynamics, then a finer second analysis is performed around the peak detected in the first analysis. In general, the time-of-flight dynamics of the second histogram is selected equal to the width of the elementary interval (bin) used for the coarse analysis. This second technique has the advantage of reducing the acquisition frequency of the sensor. Nonetheless, the amount of data generated per pixel is still large, in particular when a large number of acquisitions is necessary to improve the signal-to-noise ratio.

The acquisition of a histogram of a physical quantity may be a step prior to the estimation of a target variable dependent on the distribution of this quantity. For example, in the case mentioned hereinabove, the histogram over time of the events detected by the SPAD sensor allows estimating the time-of-arrival or the round-trip propagation time of a light pulse after reflection on an object.

The histogram may be of the spatial type instead of being of the temporal type. Thus, the histogram of the photons, emitted or reflected by an object, and received by an array of SPAD sensors may allow predicting a characteristic of this object or classifying this object amongst a plurality of possible classes.

Regardless of the type of histogram, temporal and/or spatial, the amount of data to be processed may be prohibitive, in particular when the dynamics of the physical quantity is high and/or when a high resolution is required. In some cases, the considered data are compressed and stored in memory before being restored to perform a deferred processing (off-line). Nonetheless, this solution cannot be applied when the prediction must be performed in real-time and consequently the histogram must be built online (on line) due to the difficulty of integrating considerable computing resources into the circuit of the sensor.

The object of the present invention is to provide a device for measuring the statistical distribution of a physical quantity which allows for a significant reduction in the memory footprint. A subsidiary object of the present invention is to provide a device for predicting a target variable dependent on the statistical distribution of values taken on by a physical quantity, which could operate online, as these values are acquired, without mobilising considerable computing resources. The prediction may consist of a classification operation or a regression operation.

### DISCLOSURE OF THE INVENTION

The present invention is defined by a method for compressive measurement of the statistical distribution of a physical quantity according to claim 1. Advantageous embodiments are specified in the dependent claims 2-7.

The invention also relates to a method for predicting a target variable dependent on the statistical distribution of a physical quantity, wherein said statistical distribution is measured by means of this compressive measurement method.

The invention also relates to a device for measuring the statistical distribution of a physical quantity as defined in the independent claim 8. Advantageous embodiments are specified in the dependent claims 9-15.

The invention also relates to a device for predicting a target variable dependent on the statistical distribution of a physical quantity, comprising such a device for compressive measurement of this statistical distribution.

### BRIEF DESCRIPTION OF THE DRAWINGS

Other features and advantages of the invention will appear upon reading embodiments of the invention, described with reference to the appended figures.

FIG. 1A represents an example of successive passes of acquisition of a physical quantity and the resulting histogram;

FIG. 1B represents an example of successive passes of acquisition of a physical quantity in an ideal case and the resulting histogram;

FIG. 2 schematically represents a device for building a histogram of discrete values of a physical quantity known from the prior art;

FIG. 3 schematically represents the flowchart of a method for compressive measurement of the statistical distribution of a physical quantity, according to an embodiment of the invention;

FIG. 4 schematically represents the structure of a device for compressive measurement of the statistical distribution of a physical quantity, according to a first embodiment of the invention;

FIG. 5 details a first exemplary implementation of the encoding module in the device of FIG. 4;

FIG. 6 details a second exemplary implementation of the encoding module in the device of FIG. 4;

FIG. 7 schematically represents the structure of a device for compressive measurement of the statistical distribution of a physical quantity, according to a second embodiment of the invention;

FIG. 8 details an exemplary implementation of the recursive summation module in the device of FIG. 7;

FIG. 9 schematically represents the structure of a device for compressive measurement of the statistical distribution of a physical quantity, according to a third embodiment of the invention;

FIG. 10 schematically represents the structure of a device for compressive measurement of the statistical distribution of a physical quantity, according to a fourth embodiment of the invention.

### DETAILED DISCLOSURE OF PARTICULAR EMBODIMENTS

We will consider hereinafter a measurement of the statistical distribution of a physical quantity, the measurement of this distribution being represented by a histogram of the values taken on by this physical quantity.

For example, the values taken on by this physical quantity correspond to observations of a physical signal during the occurrence of events. For illustration and without prejudice to generality, we will assume in some embodiments that this physical quantity is a time-of-arrival of a photon on a SPAD sensor or the coordinates of the point of impact of a photon on an array of SPAD sensors.

In some cases, this histogram could allow predicting a target variable dependent on the considered statistical distribution.

Thus, in the aforementioned first example, it will be possible to predict, from the histogram of the time-of-arrival of the photons, the round-trip propagation time of a light pulse being reflected on an object, this propagation time being dependent on the temporal distribution of the photons received by the sensor.

In the aforementioned second example, it will be possible, for example, to predict the class to which the image of an organ obtained by a positron emission tomograph after injection of radioactive markers belongs. The positrons emitted by this organ generate photons during annihilation thereof with electrons, these photons being detected by an array of elementary SPAD sensors. The class to which the image (or the organ itself) belongs depends on the spatial distribution of the photons received by the array of elementary sensors.

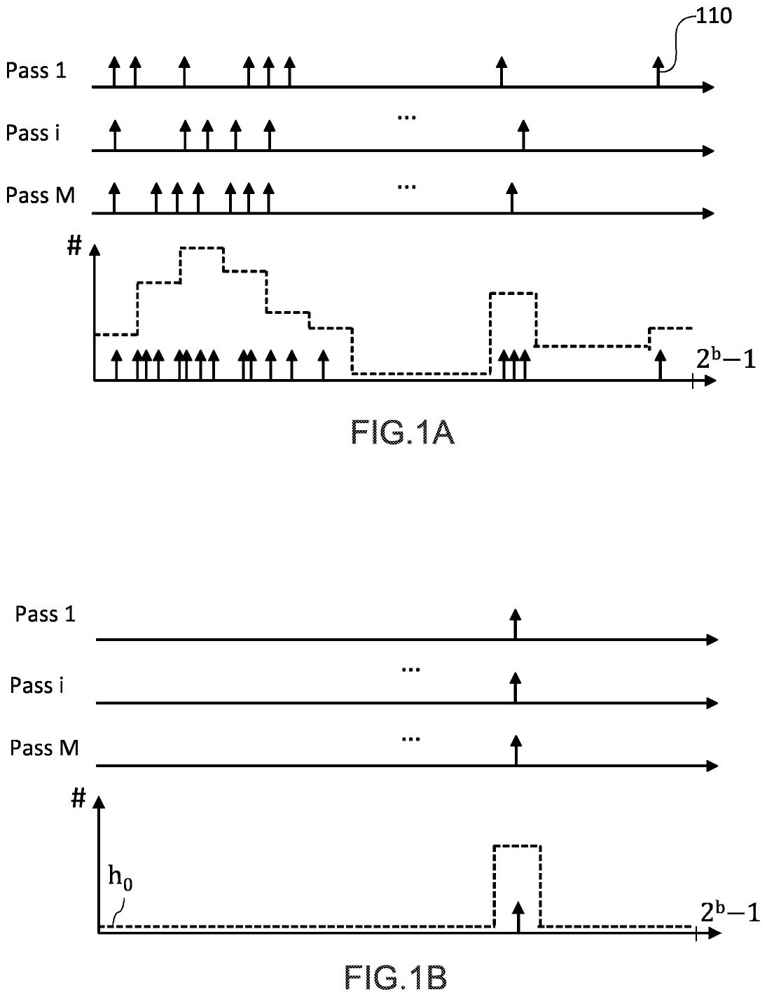

FIG. 1A represents a plurality of successive passes P₁, P₂, . . . , P_{M} of acquisition of the time-of-arrival (or time-of-flight) of photons received by a SPAD sensor, when a light pulse is sent towards and reflected by an object.

The photons detected during the successive acquisition passes Pi are denoted by the arrows 110, each detected photon corresponding to a time-of-flight (ToF) value. The time-of-flight range is quantised (or equivalently discretised) into 2^{b}−1 elementary intervals (or “bins”) ranging from 0 to (2^{b}−1)τ where τ is the duration of an elementary interval.

When a photon falls in an elementary interval during an acquisition pass, the score of this interval is incremented by 1.

In the lower portion of the figure, the histogram corresponding to the scores of the different intervals after M acquisition passes has been represented. This histogram provides a good approximation of the statistical distribution of the time-of-flight if the number M of passes is large enough.

In the illustrated example, typical of the time-of-flight statistical distribution at the output of a SPAD sensor, the statistical distribution includes a first component due to the noise and a second component due to a useful signal.

FIG. 1B represents a plurality of successive passes P₁, P₂, . . . , P_{M} of acquisition of the time-of-flight of photons received by an ideal SPAD sensor, i.e. in the absence of noise. It should be noticed that all of the scores of the different elementary intervals are negative (lower than the value h₀ corresponding to the LSB), except for that one corresponding to the round-trip propagation time of the pulse reflected by the object.

Starting from the histogram of the quantised values of the times of arrival of the photons (physical quantity), it is possible to determine the round-trip time-of-flight or the distance to the object (target variable to be predicted).

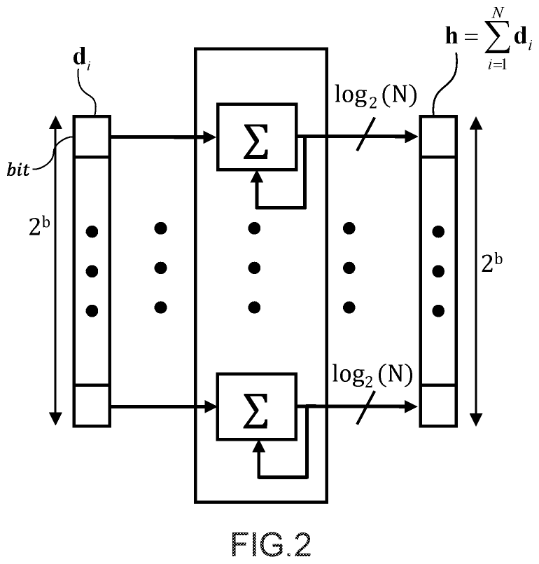

Conventionally, this histogram may be obtained by incrementation of the scores of each of the elementary intervals as represented in FIG. 2.

At each event, i.e. each time a photon is detected by the SPAD sensor, the score of the elementary interval in which the event occurs is incremented by 1. More specifically, if the dynamics of the physical quantity (time-of-flight) is quantised (discretised) over b bits, in other words if this dynamics is divided into 2^{b} elementary intervals, it is possible to represent the event occurring during the pass i by a binary vector, dᵢ with a size 2^{b}, each element corresponding to an elementary interval. All of the elements of dᵢ are zero, except for that one, equal to 1, corresponding to the interval in which the event occurs, where appropriate. The binary vector dᵢ may be considered as a code word in position with a length 2^{b}, the position of the bit “1” in the considered word providing the quantised value of the physical quantity.

The histogram of the physical quantity may be represented by the vector h in a quantisation space with a dimension 2^{b}, namely:

$$h = {\sum }_{i = 1}^{N} {d}_{i} \qquad ( 1 )$$

where N is the number of events taken into account in the histogram. The elements of h are log₂ N-bit words.

A first idea underlying the invention is to notice that a histogram may be represented by a reduced number of parameters (or latent variables) and that henceforth a compressive measurement of the histogram may be performed in a space with a reduced dimension, called measurement space by means of a compressive acquisition matrix, Ψ. Assuming that the dimension of the measurement space is K□2^{b}, the compressive acquisition matrix has a size K×2^{b} in the canonical bases of the quantisation space and of the measurement space:

The measurement vector may then be expressed in the form:

$$y = Ψ h = Ψ {\sum }_{i = 1}^{N} {d}_{i} = {\sum }_{i = 1}^{N} Ψ {d}_{i} = {\sum }_{i = 1}^{N} {ψ}_{v ( i )} \qquad ( 2 )$$

The compressive acquisition matrix Ψ may be considered as a projection matrix from a space with a dimension 2^{b} into a space with a dimension K. Since each binary vector dᵢ contains one single non-zero element equal to 1, located at the position v(i)=xᵢ, the result of the projection is simply the sum of the column-vectors ψᵥ₍ᵢ₎ of the matrix Ψ in the different positions v(i).

Advantageously, the elements of the matrix Ψ are derived from a pseudo-random (deterministic) process so that the row-vectors of Ψ are inconsistent with the canonical basis of □²^{^{b}}.

A second idea underlying the invention is to build the measurement vector y on the fly, as events occur. Indeed, the measurement vector may be built in a recursive manner at each new event providing a binary vector dᵢ:

y=y+ψᵥ₍ᵢ₎ (3)

Afterwards, the measurement vector, y, may be used as an input variable of a neural network trained beforehand, to predict a target variable. The prediction may be a regression or a classification.

If this target variable (herein a scalar) is denoted z, the latter may then be predicted by means of:

$$\hat{z} = F ( y ) = F ( {\sum }_{i = 1}^{N} {ψ}_{v ( i )} ) \qquad ( 4 )$$

where

$$y = {\sum }_{i = 1}^{N} {ψ}_{v ( i )}$$

represents the measurement vector, F(.) is the representative function of the neural network and \hat{z} is the predicted value of the target variable. According to one variant, this target variable may be multinomial (represented by a vector z), it may be predicted in a similar manner by a neural network, \hat{z}=F(y) Without prejudice to generality, we will limit ourselves hereinafter to a scalar target variable.

In some cases, it could be relevant to weight the different vectors ψᵥ₍ᵢ₎ according to the probability of occurrence of the value of the physical quantity. Thus, in this case, if these weights are denoted A, the histogram is obtained in a recursive manner by:

y=y+λᵢψᵥ₍ᵢ₎ (5)

The prediction of the target variable will then be obtained by:

$$\hat{z} = F ( {\sum }_{i = 1}^{N} {λ}_{i} {ψ}_{v ( i )} ) \qquad ( 6 )$$

For example, if the probability of occurrence of a value of the physical quantity is even lower as this value is high, the weights A could be obtained from an increasing function of xᵢ=v(i), of so as to favour the measurements with a low probability of occurrence. This increasing function could be selected linear:

λᵢ=a+bv(i) (7)
where a,b are positive integers.

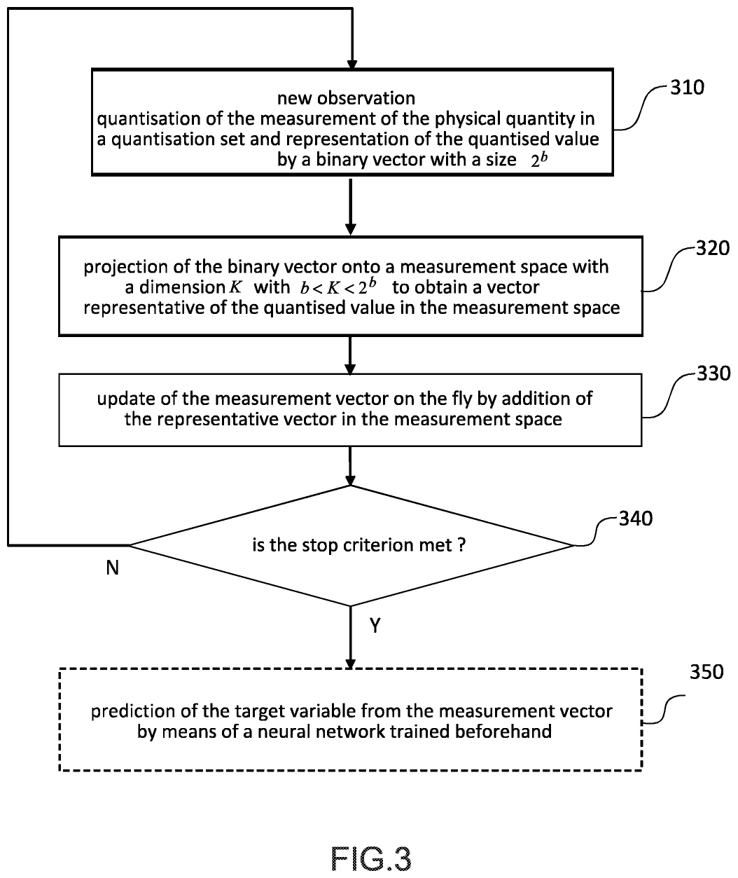

FIG. 3 schematically represents the flowchart of a method for compressive measurement of the statistical distribution of a physical quantity, according to a general embodiment of the invention.

This measurement method is iterative, each iteration comprising:
a first step, 310, in which, at each event, a new quantised value of the physical quantity (real) is observed. This quantised value results from a quantisation of the physical quantity by means of a tiling of the first space into elementary tiles, for example a tiling of a time range into elementary intervals or a spatial tiling of a sensor into elementary sensors. The quantised value of the physical quantity may be represented as a binary vector with a size 2^{b} where 2^{b} is the cardinal of the quantisation set, i.e. the number of possible quantised values of said physical quantity (for example number of quantisation tiles or steps in the range of variation of the physical quantity). This vector has one single non-zero element, equal to 1, at the position representing the quantised value.
a second step, 320, in which based on the quantised value, a vector representative of this value in a measurement space with a dimension K is generated, said representative vector being obtained from the quantised value by means of an injective function from the set of quantised values to the measurement space. The dimension K is such that b<K<2^{b}.

This representative vector may be obtained by projection of the binary vector of the quantised physical quantity onto a subspace of □^{N} with a dimension K generated by the row-vectors of the matrix Ψ.

As indicated hereinabove, the projection of the binary vector dᵢ onto this subspace is none other than the column-vector ψᵥ₍ᵢ₎.

The elements of the column-vector ψᵥ₍ᵢ₎ may be generated by means of operations of permutation, replication, concatenation of subsets of bits of v̅ᵢ̅ (binary representation of the position v(i)) as well as by combinatory logic operations on the bits resulting from these operations.

The binary elements of the column-vector may be associated with signed binary values, a first signed binary value (for example the signed binary value +1) being associated with the bit “1” and a second signed binary value (for example the signed binary value −1), opposite to the first one, being associated with the bit “0”.
a third step, 330, in which the measurement vector is updated, on the fly, by means of said representative vector, namely the projection of the binary vector into the measurement space. This update is performed, element-by-element of the measurement vector, by incrementing this element if the corresponding element of the representative vector is equal to “1”, and by decrementing it if the corresponding element of the representative vector is equal to “0”.

Different variants may be considered, after a predetermined number of iterations, M:

First of all, it is possible, starting from the measurement vector y to rebuild the histogram in the quantisation space by means of a constrained regularisation algorithm. For example, it is possible to rebuild the histogram by means of the pseudo-inverse matrix Ψ^{†}.

According to an advantageous application, it is possible to predict a target variable (scalar or multimodal), dependent on the statistical distribution of the physical quantity, by means of a neural network trained beforehand. The neural network uses as an input variable the measurement vector Y, with a dimension substantially smaller than the dimension of the quantisation space.

This variant has been represented optionally in FIG. 3. When the predetermined number of iterations is reached, or more generally, when a stop criterion is met at step 340, it is possible to predict the target variable, at 350, using a neural network trained beforehand, from the measurement vector y of the histogram.

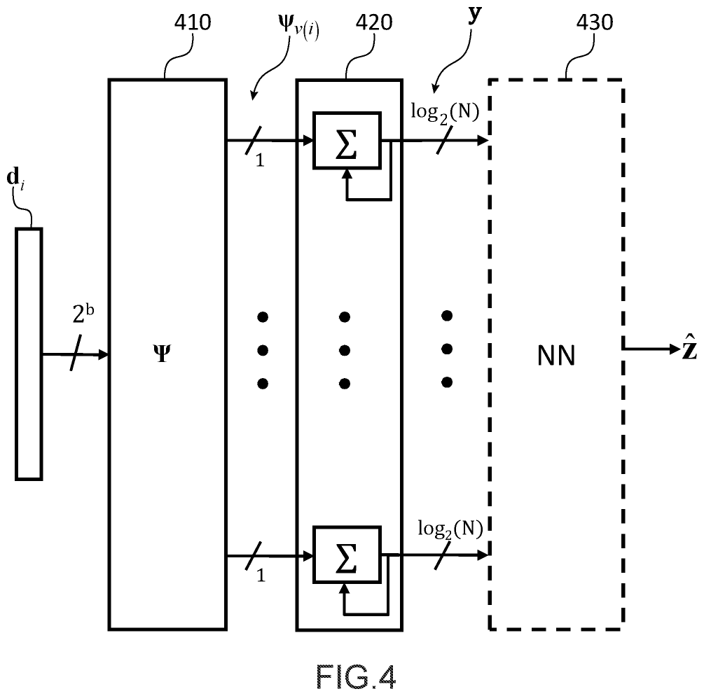

FIG. 4 schematically represents the structure of a device for compressive measurement of the statistical distribution of a physical quantity, according to a first embodiment of the invention.

The device receives as an input, at each new event or observation, a binary vector, dᵢ, with a size 2^{b}, representing the quantised value of the physical quantity, for example the time-of-arrival of a photon. This binary vector may be considered as a code word in position indicating the quantised value of the physical quantity in the quantisation space.

The binary vector dᵢ is provided to a projection module 410 which projects it onto the measurement space, with a dimension K and more specifically onto the row-vectors of the matrix Ψ.

The result of the projection is a vector ψᵥ₍ᵢ₎ with a size K. The elements of ψᵥ₍ᵢ₎ are binary elements (associated with binary values signed +1 or −1).

The module 420 performs a summation in the second space in a recursive manner. Each element of ψᵥ₍ᵢ₎ is added to the corresponding element of y according to the expression (3).

The output vector of the summation module is a measurement vector y with a size K whose elements are signed binary words with a size log (N) This vector is representative of the projection of the histogram in the second space.

As indicated before, the measurement vector y may serve as an input variable to the artificial neural network, 430.

The neural network, 430, then performs a prediction of the target variable z from the input variable y. This prediction, \hat{z}, may be a scalar value (for example a time-of-arrival of a light pulse in the previous example) or a class (class of an object whose discretised spectrum is observed) or vectorial (multimodal target value).

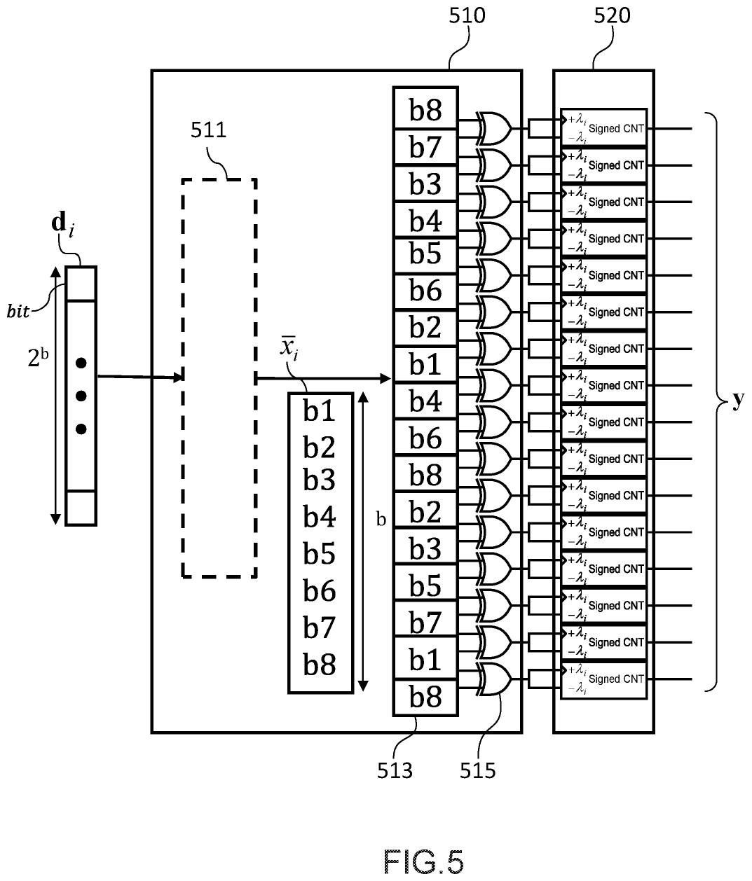

FIG. 5 details a first exemplary implementation of the projection module in the device of FIG. 4.

In this exemplary implementation, we have considered b=8.

Optionally, the projection module 510 comprises a transcoder for encoding the binary vector dᵢ into a binary word (weighted), 511, x̅ᵢ̅ encoding over b bits the quantised value of the physical quantity. This transcoder is not present if the sensor directly outputs the considered binary word.

The binary word x̅ᵢ̅ is provided to a randomisation circuit. This circuit includes a first layer, 513, in which bit duplication and shuffling operations are performed by means of permutation, separation and concatenation operations. In the illustrated example, the first layer transforms the 8-bit binary word x̅ᵢ̅=b₁b₂ . . . b₈ (where b₁ is the MSB) into a first randomised 17-bit binary word b₈b₇b₃b₄b₅b₆b₂b₄b₆b₈b₂b₃b₅b₇b₁b₈. A second layer, 515, performs combinatory logic operations on the first randomised binary word, herein exclusive OR operations between consecutive bits of this binary word. The second layer provides a second randomised binary word whose bits respectively control the incrementation (bit value equal to 1) and the decrementation (bit value equal to 0) of 16 counters of a counting circuit 520. The counting circuit carries out the recursive summation according to the expression (3).

The result at the output of the counting circuit is the vector y with a size K=16 representing the histogram projected into the measurement space. The histogram is herein compressed by a factor of 16 (2^{b}/K).

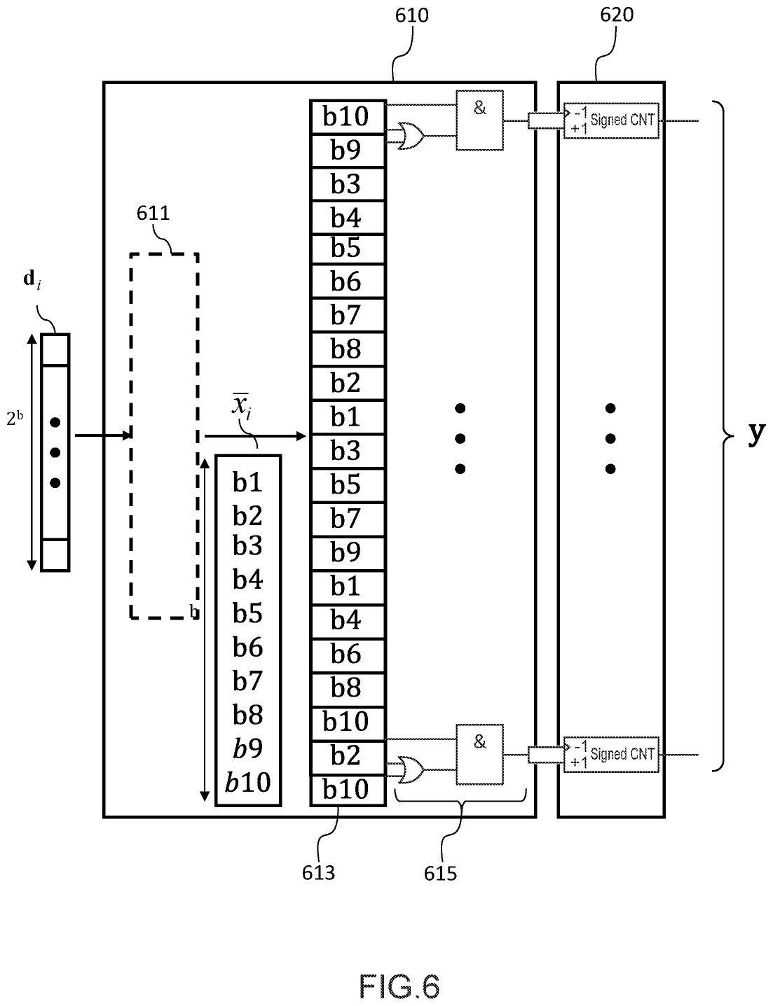

FIG. 6 details a second exemplary implementation of the projection module in the device of FIG. 4.

In this exemplary implementation, we have considered b=10. Like in the first example, the projection module, 610, comprises an optional transcoder, 611, converting the binary vector dᵢ into a weighted binary word, x̅ᵢ̅ as well as a randomisation circuit.

The randomisation circuit comprises a first layer, 613, for duplicating and shuffling bits transforming the 10-bit binary word x̅ᵢ̅=b₁b₂ . . . b₁₀ into a first randomised 21-bit binary word b₁₀b₉b₃b₄b₅b₆b₇b₈b₂b₁b₃b₅b₇b₉b₁b₄b₆b₈b₁₀b₂b₁₀. A second layer, 615, performs combinatory logic operations on the bits of the first randomised binary word to provide a second randomised 20-bit binary word whose bits control respectively the incrementation (bit value equal to 1) and the decrementation (bit value equal to 0) of 16 counters of the counting circuit 620. In this example, the second layer of the randomisation circuit comprises a first sub-layer made up of OR gates and a second sub-layer made up of AND gates.

The result at the output of the counting circuit is a vector y with a size K=20. The histogram is herein compressed by a factor of 51 (2^{b}/K).

A person skilled in the art will be able to design other projection modules using different examples of randomisation circuits yet without departing from the scope of the present invention.

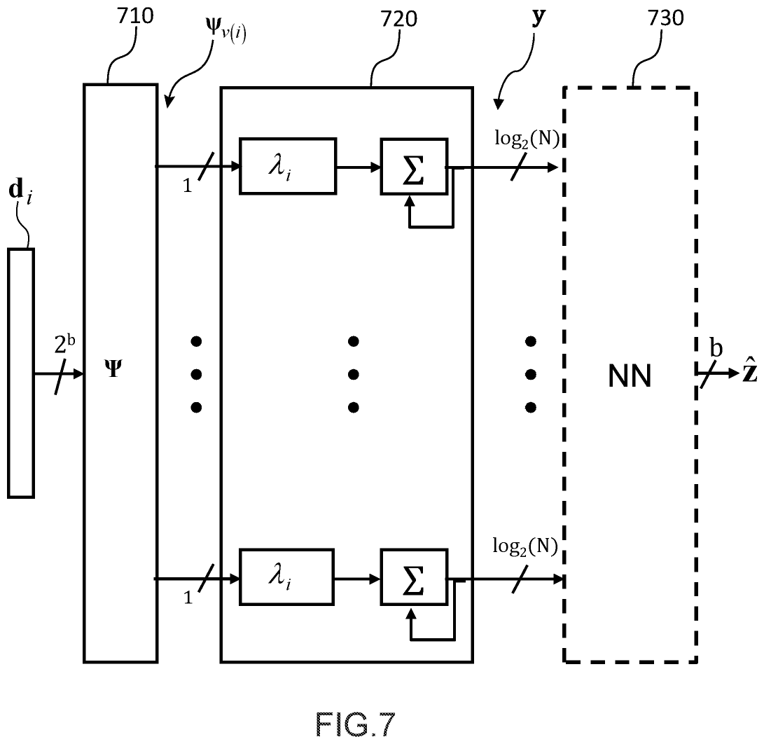

FIG. 7 schematically represents the structure of a device for compressive measurement of the statistical distribution of a physical quantity, according to a second embodiment of the invention.

This embodiment includes a projection module, 710, a recursive summation module, 720, like in the first embodiment. Nonetheless, unlike the first embodiment, the recursive summation module 720 weights each component of the vector ψᵥ₍ᵢ₎ at the output of the projection module with a weight λᵢ before summing it to the current vector y. The weights λᵢ may be selected so as to favour the contributions of the measurements having a low probability of occurrence in the histogram.

The measurement vector y may serve as an input variable to the neural network 730 for the prediction of the target variable, scalar or vectorial (multinomial) like before.

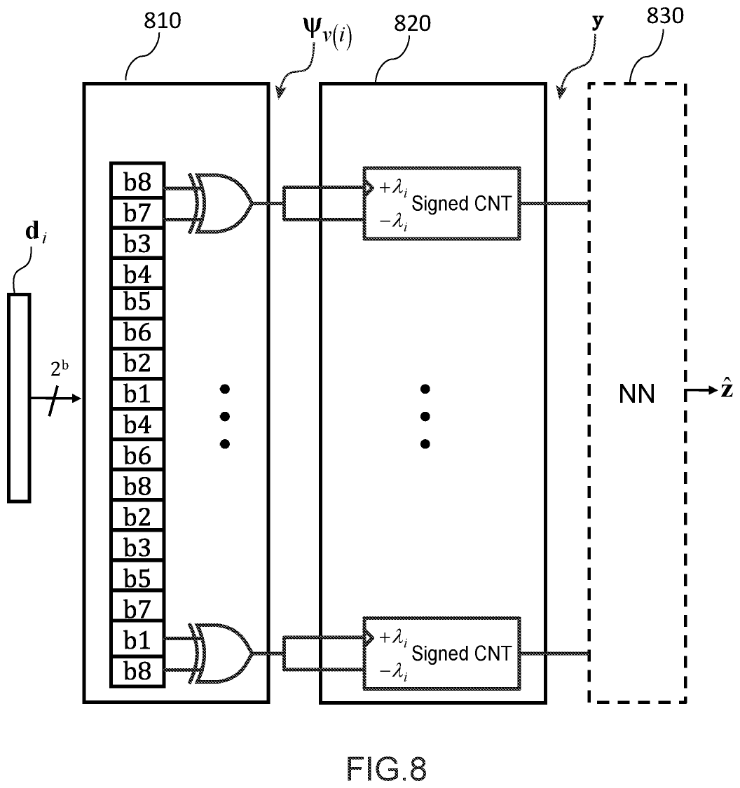

FIG. 8 details an exemplary implementation of the recursive summation module in the device of FIG. 7.

The projection module, 810 represented in FIG. 8 is herein identical to that of FIG. 5. On the other hand, the recursive summation module is implemented by a counting circuit 820 comprising 16 counters, each counter being decremented (resp. incremented) by a value A (positive integer) when the corresponding bit at the output of the projection module is equal to 0 (respectively 1).

The measurement vector y may serve like before as an input variable to the neural network 830 for the prediction of the target variable, scalar or vectorial.

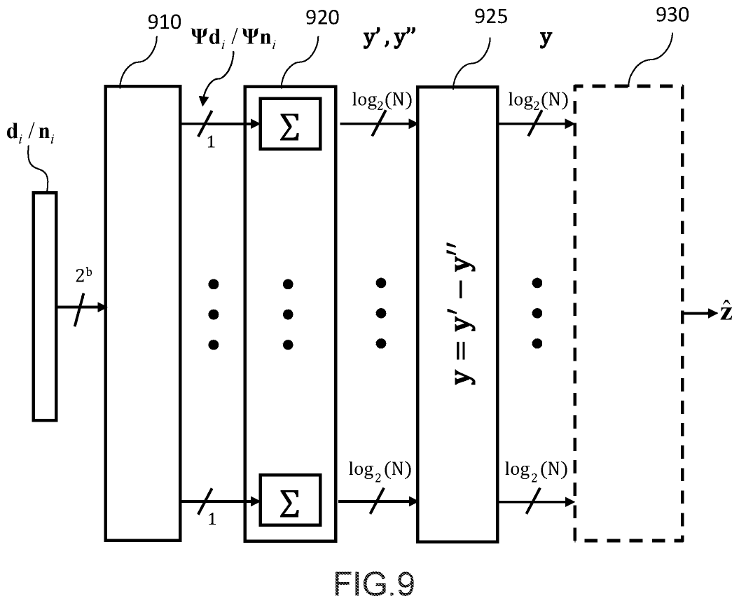

FIG. 9 schematically represents the structure of a device for compressive measurement of the statistical distribution of a physical quantity, according to a third embodiment of the invention.

This embodiment differs from the previous embodiments in that it includes at the output a noise subtraction module, 925, allowing subtracting from a vector, y′, representing a histogram of the quantised values of the noisy signal, in the ‘measurement space, a vector y″, with the same dimension representing a histogram of the quantised values of the noise alone, in this same space.

This embodiment assumes that it is possible to make a noise measurement off the useful signal, for example by cutting off the signal source or else by means of a synchronous detection with a pulsed signal.

In any case, a projection is performed using the same device, but in a time-multiplexed manner, in the same measurement space (in other words onto the row-vector of Ψ) respectively of the signal and of the noise, thanks to the projection module, 910, and the recursive summation module, 920. The vector y″ representative of the histogram of the quantised values of the noise alone, in the measurement space, could be stored locally in the subtraction module 925 before being subtracted in this same module from the vector y′ representative of the histogram of the quantised values of the noisy signal, in the same space.

Alternatively, the recursive summation module could comprise two banks of counters, a first bank being dedicated to the noise histogram (projected into the measurement space) and a second bank being dedicated to the histogram of the noisy signal (projected into this same space). The noise measurements and those of the noisy signal could be interlaced so as to follow the evolution of the noise.

In any case, the difference y=y′−y″ representing the difference between the histogram of the quantised noisy values, in the measurement space, and that of the discretised values of the noise alone, in this same space, may serve as an input variable to an artificial neural network, 930, trained beforehand, to predict the target variable (scalar or vectorial).

Alternatively, the neural network may include a differential input formed by a first branch receiving the first input variable, y′, and by a second branch receiving the second input variable, y″.

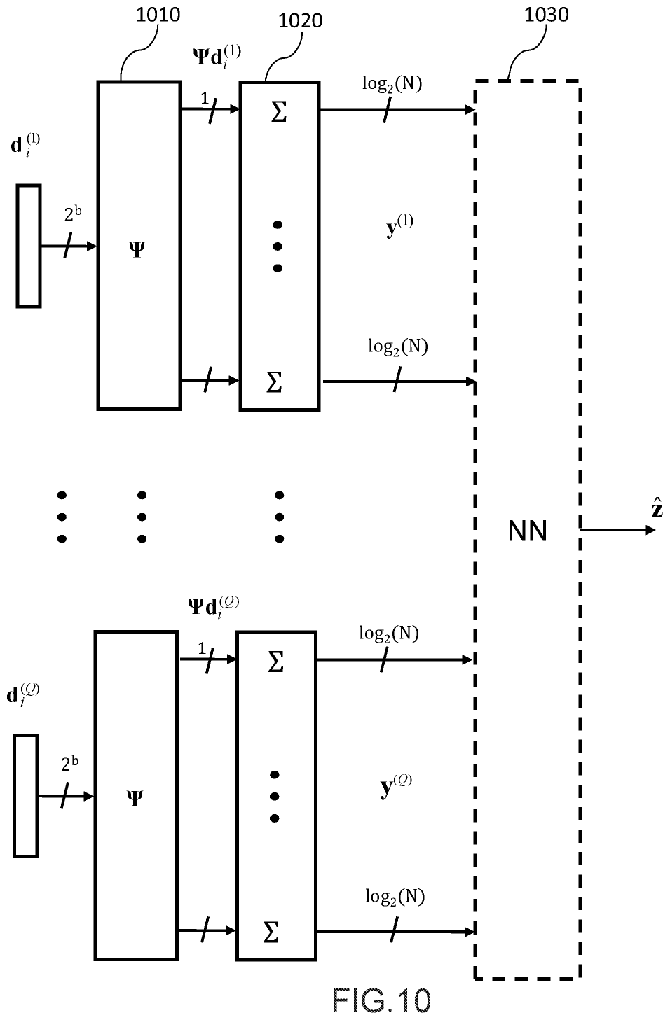

FIG. 10 schematically represents the structure of a device for compressive measurement of the statistical distribution of a physical quantity, according to a fourth embodiment of the invention.

This embodiment differs from the previous ones in that it comprises a plurality Q of histogram measurement chains operating in parallel, each chain comprising a projection module, 1010 and a recursive summation module, 1020.

For example, these histogram measurement chains are respectively associated with Q SPAD sensors of an array of sensors.

The quantised values of the physical quantities derived from the different sensors are denoted dᵢ⁽¹⁾, . . . , dᵢ^{(Q)}.

The vectors y⁽¹⁾, . . . , y⁽²⁾ representing the respective histograms of the quantised values derived from the different sensors, projected into the same measurement space, may be supplied in a concatenated form to a global neural network, trained beforehand to predict the target variable (scalar or multinomial).

For example, the neural network could in this case be of the convolutional type to take into account interactions between neighbouring pixels.

The neural network may be a deep network adapted to provide a high-level prediction, such as online image recognition.

Where appropriate, the different measurement chains may carry out different processing, in particular by providing for different quantisation steps and/or different compression factors 2^{b}/K, depending on the relevance of the sensor in the prediction of the target variable.

Furthermore, the fourth embodiment may be combined with the third embodiment to respectively subtract from the vectors y′⁽¹⁾, . . . , y′⁽²⁾ the vectors y″⁽¹⁾, . . . , y″⁽²⁾ representative of the noise histograms associated with the different sensors, in the measurement space. According to one variant, one of the acquisition chains and consequently one of the sensors could be specialised in the acquisition of the noise histogram, then assumed to be relevant for all of the other sensors and the vector y″⁽ⁱ⁾ thus obtained could be subtracted from the vectors y^{i(q)}, q−1, . . . , Q, q≠l, at the input of the neural network.

In all of the embodiments of the device for predicting a target variable (scalar or multinomial), the neural network would have been trained beforehand in a prior phase from histograms labelled by values of the target variable (for example numerical values for a regression and class identifiers for a classification), in a manner known to a person skilled in the art.

What is claimed is:

1. A method for compressive measurement of the statistical distribution of a physical quantity, to provide a measurement vector of this distribution, the method including an iterative loop comprising:
(a) observing a quantised value of said physical quantity provided by the sensor, said quantised value being represented by a binary vector with a size 2^{b} one single element of which is non-zero and equal to one, the position of this element representing said quantised value in a quantisation set with a cardinal 2^{b};
(b) generating, from said quantised value, a vector representative of this quantised value in a measurement space with a dimension K, with b<K<2^{b}, by means of an injective function from set of quantised values to the measurement space;
(c) updating the measurement vector on the fly from the vector representative of the quantised value obtained in the previous step, an element of the measurement vector being incremented if the corresponding element of the representative vector takes on a first binary value and decremented if the corresponding element of the representative vector takes on a second binary value, inverse of the first one.

2. The method for compressive measurement of the statistical distribution of a physical quantity according to claim 1, wherein the vector representative of the quantised value is obtained by projecting said binary vector onto a plurality K of vectors, the elements of each of these vectors being binary values derived from a pseudo-random sequence.

3. The method for compressive measurement of the statistical distribution of a physical quantity according to claim 1, wherein the injective function comprises a conversion of the binary vector with a size 2^{b} into a weighted binary word with a size b encoding the position of the non-zero element in said binary vector, a step of randomising the bits of the weighted binary word to provide a first randomised binary word, followed by a combinatory logic step on the bits of this first randomised binary word to obtain a second randomised binary word with a size K, each bit of the second randomised binary word incrementing or decrementing a counter by one increment depending on whether it is equal to said first binary value or to said second binary value.

4. The method for compressive measurement of the statistical distribution of a physical quantity according to claim 3, wherein the first randomised binary word is obtained by duplicating and shuffling the bits of the weighted binary word.

5. The method of compressive measurement of the statistical distribution of a physical quantity according to claim 3, wherein the increment is independent of the quantised value of the physical quantity.

6. The method of compressive measurement of the statistical distribution of a physical quantity according to claim 3, wherein the increment depends on the quantised value of the physical quantity, the increment being selected even greater in absolute value as the probability of occurrence of the quantised value of the physical quantity is low.

7. A method for predicting a target variable dependent on the statistical distribution of a physical quantity, wherein said statistical distribution is measured by means of the compressive measurement method according to claim 1 and that the target variable is predicted, by means of an artificial neural network trained beforehand, from said measurement vector.

8. A device for measuring the statistical distribution of a physical quantity, to provide a measurement vector of this distribution, the device comprises:
(a) a sensor for providing a quantised value of the physical quantity, said quantised value being represented by a binary vector with a size 2^{b} one single element of which is non-zero and equal to one, the position of this element representing said quantised value in a set of quantised values with a cardinal 2^{b};
(b) a projection module for obtaining a vector representative of the quantised value by projecting said binary vector onto a plurality K of vectors subtending a measurement space with a dimension K, with b<K<2^{b};
(c) a recursive summation module for updating the measurement vector on the fly from the vector representative of the quantised value obtained in the previous step, an element of the measurement vector being incremented if the corresponding element of the representative vector takes on a first binary value and decremented if the corresponding element of the representative vector takes on a second binary value, inverse of the first one.

9. The device for compressive measurement of the statistical distribution of a physical quantity according to claim 8, wherein the vector representative of the quantised value is obtained by projecting said binary vector onto a plurality K of vectors, the elements of each of these vectors being binary values derived from a pseudo-random sequence.

10. The device for compressive measurement of the statistical distribution of a physical quantity according to claim 8, wherein the projection module comprises an encoder for converting the binary vector with a size 2^{b} into a weighted binary word, with a size b.

11. The device for compressive measurement of the statistical distribution of a physical quantity according to claim 10, wherein the projection module comprises a randomisation circuit comprising a first layer adapted to duplicate and shuffle the bits of the weighted binary word to provide a first randomised binary word, and a second layer adapted to perform combinatory logic operations on the bits of this first randomised binary word to provide, as a vector representative of the quantised value, a second randomised binary word with a size K.

12. The device for compressive measurement of the statistical distribution of a physical quantity according to claim 10, wherein the recursive summation module comprises a bank of K counters, each counter receiving a bit of the second randomised binary word, said bit incrementing or decrementing said counter by one increment depending on whether it is equal to the first binary value or to the second binary value.

13. The device for compressive measurement of the statistical distribution of a physical quantity according to claim 12, wherein the increment is independent of the discrete value of the physical quantity.

14. The device for compressive measurement of the statistical distribution of a physical quantity according to claim 12, wherein the increment depends on the discrete value of the physical quantity, the increment being even greater in absolute value as the probability of occurrence of the quantised value of the physical quantity is low.

15. The device for compressive measurement of the statistical distribution of a physical quantity according to claim 8, wherein it comprises a subtraction module at the output of the recursive summation module for storing a first measurement vector obtained in the absence of a signal on the sensor and to subtract it from a second measurement vector obtained in the presence of a signal on the sensor.

16. A device for predicting a target variable dependent on the statistical distribution of a physical quantity, comprising the device for compressive measurement of the statistical distribution according to claim 8 as well as an artificial neural network trained beforehand receiving as an input variable the measurement vector and providing as output a prediction of the target variable.

17. A device for predicting a target variable dependent on the statistical distribution of a physical quantity, comprising a plurality of the devices for compressive measurement of the physical quantity according to claim 8, each compressive measurement device being associated with a distinct elementary sensor, each compressive measurement device comprising a projection module and a recursive summation module, the prediction device further comprising an artificial neural network trained beforehand receiving as an input variable the measurement vectors respectively provided by the compressive measurement devices, and providing as output a prediction of the target variable.

18. A device for predicting a target variable dependent on the statistical distribution of a physical quantity, comprising the device for compressive measurement of the statistical distribution according to claim 15, as well as an artificial neural network trained beforehand, receiving as an input variable the difference between the first measurement vector and the second measurement vector and providing as output a prediction of the target variable.

19. The device for predicting a target variable dependent on the statistical distribution of a physical quantity according to claim 16, wherein the prediction of the target variable is a regression operation or a classification operation.
